(19) United States
(12) Patent Application Publication
(10) Pub. No.: US 2011/0133808 A1
(43) Pub. Date: Jun. 9, 2011

(54) APPARATUS

(75) Inventor: Hiroshi AKAMATSU, Tokyo (JP)

(73) Assignee: ELPIDA MEMORY, INC., Tokyo (JP)

(21) Appl. No.: 12/963,176

(22) Filed: Dec. 8, 2010

(30) Foreign Application Priority Data
Dec. 9, 2009 (JP) 2009-279489

(51) Int. Cl. H03H 11/26

(52) U.S. Cl. 327/276

(57) ABSTRACT

An apparatus has a delay circuit, a delay control circuit which detects the delay time of the delay circuit and generates a delay adjustment signal based upon the detection result, and a delay adjustment circuit operable to adjust delay time of the delay circuit in response to the delay adjustment signal.

This application is based upon and claims the benefit of priority from Japanese patent application No. 2009-279489, filed on Dec. 9, 2009, the disclosure of which is incorporated herein in its entirety by reference.

### BACKGROUND

The present invention relates to an apparatus, and more particularly to a semiconductor apparatus including a delay circuit.

Some semiconductor devices have a delay circuit for the purpose of adjusting the timing of signals. It is preferable for a delay circuit to have a delay time that is identical to a designed delay time. Because of variations in manufacturing, however, the delay time of the delay circuit may not necessarily be the same as desired. Therefore, a semiconductor chip should be configured to be capable of adjusting a delay time of a delay circuit after it has been manufactured.

An example of related semiconductor devices has a delay circuit including a plurality of capacitive elements arranged in parallel between a signal line path and a fixed potential. Those capacitive elements can selectively be connected to and disconnected from the signal line path. For example, this type of technology is disclosed in Japanese Unexamined Patent Publication No. JP-A 2006-172641 (Patent Document 1).

With this configuration, the delay time of the delay circuit can be adjusted by the capacity of the capacitive elements connected to the signal line path.

### SUMMARY

In order to adjust the delay time of the delay circuit of the semiconductor apparatus disclosed in Patent Document 1, the delay time of the signal line path is first measured in a state in which no capacitive elements are connected. Then, based upon the measurement results, it is determined which capacitive elements should be connected to the signal line path. Subsequently, based upon the determination, a control code for individually connecting the capacitive elements to or disconnecting the capacitive elements from the signal line path is written into a writable memory device from the outside of the chip. As a result, the capacitive elements are individually connected to or disconnected from the signal line path, so that the delay time of the delay circuit is adjusted.

Thus, the semiconductor apparatus disclosed in Patent Document 1 requires a measurement test process of measuring the delay time of the delay circuit and a writing process of writing a control code produced based upon the test results into a memory device after the semiconductor chip has been manufactured. Additionally, if a fuse is used for the memory device, the semiconductor apparatus requires a confirmation test process of examining whether the fuse has correctly been disconnected, in addition to the writing process (fuse disconnection process).

Therefore, the semiconductor apparatus disclosed in Patent Document 1 requires a plurality of processes in order to adjust the delay time of the delay circuit. Therefore, cost for those test processes after the semiconductor chip has been manufactured would problematically increase.

The present invention seeks to provide an apparatus which can solve all or part of the aforementioned problems.

In one embodiment, there is provided an apparatus that has a delay circuit, a control circuit operable to detect a period of time corresponding to a delay time of the delay circuit and generate a delay adjustment signal based upon the detection result, and a delay adjustment circuit operable to adjust the delay time of the delay circuit in response to the delay adjustment signal.

With the above apparatus, the period of time corresponding to the delay time of the delay circuit is detected. The delay time of the delay circuit is adjusted based upon the detection results. Therefore, a measurement test process of measuring the delay time of the delay circuit and a writing process are unnecessary after the chip has been manufactured. Accordingly, testing cost can be reduced.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing an overview of a semiconductor apparatus according to a first embodiment of the present invention;

FIG. 2 is a block diagram showing an overview of a DRAM included in the semiconductor apparatus of FIG. 1;

FIG. 3 is a circuit diagram showing an example of a delay circuit included in a control circuit of the DRAM of FIG. 2;

FIG. 4 is a block diagram showing an example of a delay control circuit included in the control circuit of the DRAM of FIG. 2;

FIG. 5 is a circuit diagram showing an example of a reference delay signal buffer included in the delay control circuit of FIG. 4;

FIG. 6 is a circuit diagram showing an example of a replica delay circuit included in the delay control circuit of FIG. 4;

FIG. 7 is a waveform chart of various signals for understanding operation of the replica delay circuit;

FIG. 8 is a circuit diagram showing an example of a delay adjustment judgment circuit included in the delay control circuit of FIG. 4;

FIGS. 9A and 9B are waveform charts of signals at several points of the delay adjustment judgment circuit of FIG. 8;

FIG. 10 is a waveform chart of various signals for explanation of a delay calibration operation of the semiconductor apparatus shown in FIG. 1, which uses a specific command;

FIG. 11 is a circuit diagram showing an example of a delay circuit included in a semiconductor apparatus according to a second embodiment of the present invention;

FIG. 12 is a circuit diagram showing an example of a replica delay circuit included in the semiconductor apparatus according to the second embodiment of the present invention;

FIG. 13 is a circuit diagram showing an example of a delay circuit included in a semiconductor apparatus according to a third embodiment of the present invention;

FIG. 14 is a circuit diagram showing an example of a delay control circuit included in the semiconductor apparatus according to the third embodiment of the present invention;

FIG. 15 is a circuit diagram showing an example of a replica delay circuit included in the delay control circuit of FIG. 14;

FIG. 16 is a circuit diagram showing an example of a delay adjustment judgment circuit included in the delay control circuit of FIG. 14;

FIGS. 17A and 17B are waveform charts of signals at several points of the delay adjustment judgment circuit of FIG. 16;

FIG. 18 is a circuit diagram showing an example of a delay circuit included in a semiconductor apparatus according to a fourth embodiment of the present invention;

FIG. 19 is a circuit diagram showing an example of an inverter circuit with a control terminal that is used in the delay circuit of FIG. 18; and

FIG. 20 is a circuit diagram showing an example of a replica circuit included in the semiconductor apparatus according to the fourth embodiment of the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

A semiconductor memory device will be described as an example of a semiconductor apparatus. The present invention is not limited to a semiconductor memory device and may be applied to any apparatus as long as the apparatus has a delay circuit. A delay circuit having a plurality of stages of inverter circuits being connected will be described as an example of a delay circuit. However, the delay circuit may have other configurations such as simple wire lines.

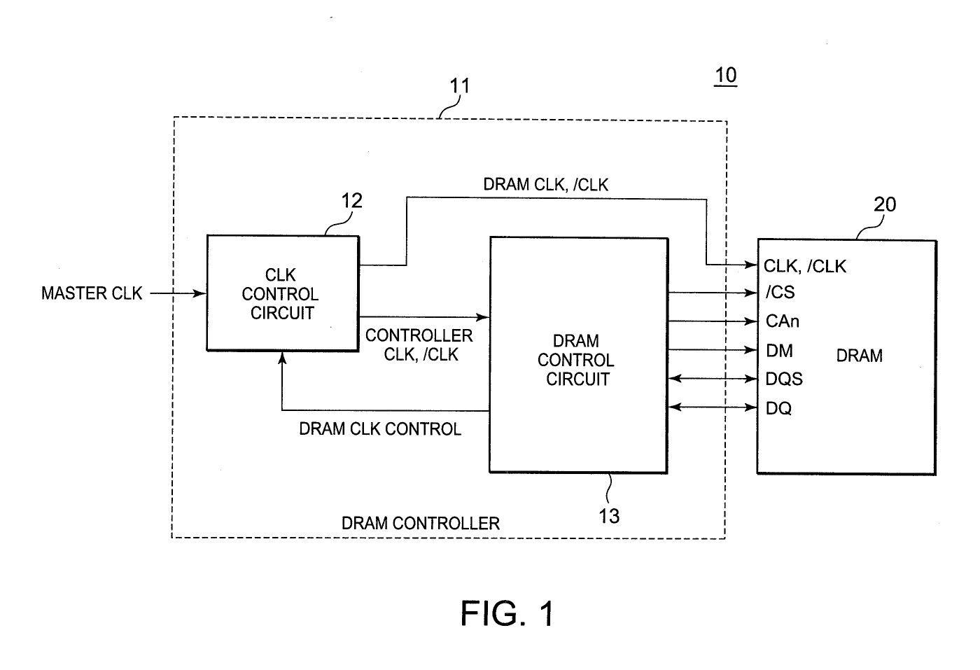

FIG. 1 is a block diagram showing an overview of a semiconductor apparatus 10 according to a first embodiment of the present invention.

The semiconductor apparatus 10 of FIG. 1 has a dynamic random access memory (DRAM) controller 11 and a DRAM 20 controlled by the DRAM controller 11.

The DRAM controller 11 includes a clock (CLK) control circuit 12 and a DRAM control circuit 13.

The clock control circuit 12 is operable to generate a DRAM clock and inverse clock (CLK and /CLK) and a control circuit clock and inverse clock (CLK and /CLK) in response to a master clock from an upstream apparatus (not shown).

The DRAM control circuit 13 operates in response to the control circuit clock and inverse clock and controls the DRAM 20. Specifically, the DRAM control circuit 13 is operable to output a chip select signal (/CS), a command-address signal (CAn), a data mask signal (DM), and a data strobe signal (DQS) to the DRAM 20. Furthermore, the DRAM control circuit 13 is operable to transmit a data signal (DQ) to the DRAM 20 and receive a data signal (DQ) from the DRAM 20. Moreover, the DRAM control circuit 13 is operable to generate a DRAM clock control signal and output the DRAM clock control signal to the clock control circuit 12.

The clock control circuit 12 is operable to determine a cycle of the DRAM clock and inverse clock based upon the DRAM clock control signal from the DRAM control circuit 13.

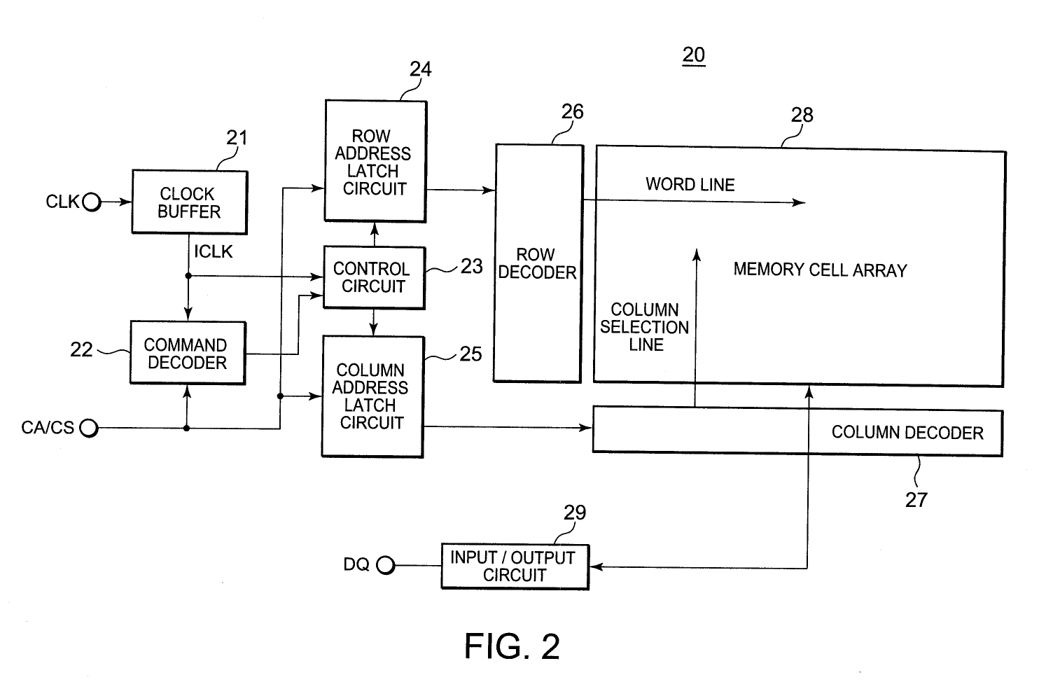

FIG. 2 is a block diagram showing an overview of the DRAM 20. Components that are not directly relevant to the present invention, such as a data mask signal DM, are omitted from the illustration. Furthermore, the command-address signal (CAn) and the chip select signal (/CS) are illustrated as one signal CA/CS.

The DRAM 20 of FIG. 2 includes a clock buffer 21, a command decoder 22, a control circuit 23, a row address latch circuit 24, a column address latch circuit 25, a row decoder 26, a column decoder 27, a memory cell array 28, and an input/output circuit 29.

The clock buffer 21 is operable to buffer the DRAM clock signal CLK supplied from the DRAM controller 11 and generate an internal clock signal ICLK. The internal clock signal ICLK is supplied to the command decoder 22 and the control circuit 23, respectively.

The command decoder 22 is operable to output a decode signal to the control circuit 23 in response to a command included in the command-address and chip select signals (CA/CS), which are inputted from the DRAM controller 11.

The control circuit 23 is operable to output a control signal to the row address latch circuit 24 and the column address latch circuit 25, respectively, in response to the decode signal from the command decoder 22.

The row address latch circuit 24 and the column address latch circuit 25 are operable to respectively latch a row address signal and a column address signal externally inputted, which are part of CA/CS, in response to the control signal from the control circuit 23 and to output those signals to the row decoder 26 and the column decoder 27, respectively.

The row decoder 26 and the column decoder 27 are operable to activate memory cells designated by the row address signal and the column address signal respectively supplied from the row address latch circuit 24 and the column address latch circuit 25.

The memory cell array 28 has a plurality of arrayed memory cells. Those memory cells are connected to a word line for each row and connected to a column selection line for each column. The word lines are connected to the row decoder 26, and the column selection lines are connected to the column decoder 27. Each memory cell is selectively activated by the row decoder 26 and the column decoder 27, so that data are read and written.

The input/output circuit 29 is operable to output data read from the activated memory cells to the DRAM controller 11 via DQ pins while only one DQ pin is illustrated in FIG. 2. The input/output circuit 29 is also operable to supply writing data, which have been supplied to the DQ pins from the DRAM controller 11, to the activated memory cells.

The DRAM of FIG. 2 is operable to write data into or read from activated memory cells in response to a command inputted from the DRAM controller 11. In order to correctly perform this operation, the control circuit 23 includes a delay circuit for delaying a control signal. The delay circuit includes a delay adjustment circuit for adjusting the delay time of the delay circuit. The control circuit 23 also includes a delay control circuit for controlling the delay adjustment circuit.

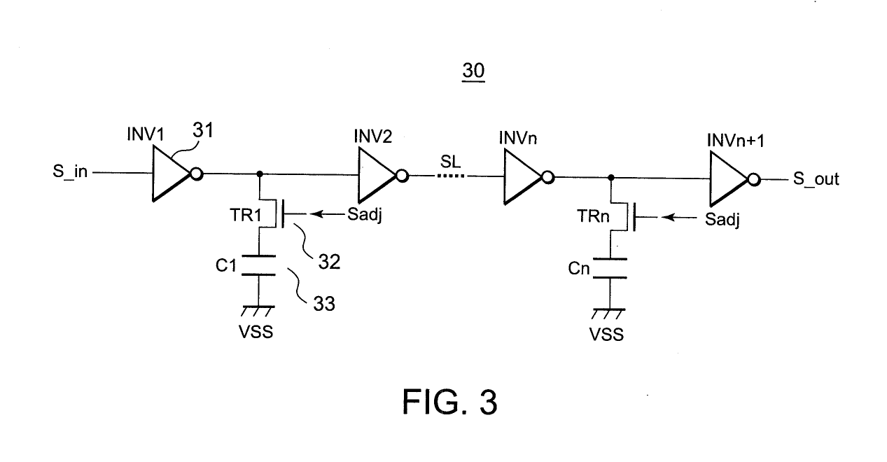

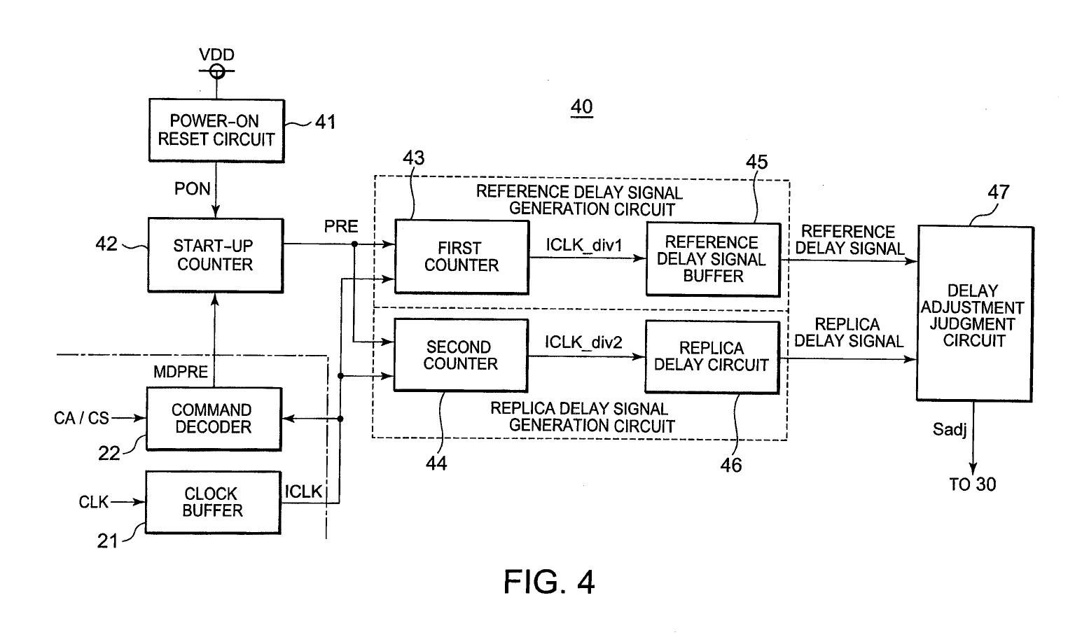

FIG. 3 shows an example of the delay circuit including the delay adjustment circuit, and FIG. 4 shows an example of the delay control circuit.

The delay circuit 30 of FIG. 3 has n+1 inverter circuits 31 (INV1 to INVn+1), n control transistors 32 (Tr1 to Trn), and n capacitive elements 33 (C1 to Cn) where n is 1 or an odd number larger than 1.

For example, each of the inverter circuits 31 is a CMOS inverter. A plurality of inverter circuits 31 are connected in series so as to form a signal line SL (or a delay circuit portion). The number n+1 of the inverter circuits 31 may be set arbitrarily according to a desired delay time. Nevertheless, the number n+1 of the inverter circuits 31 should be an even number so that the logic of an output signal S_out agrees with the logic of an input signal S_in. The delay circuit portion delays the input signal S_in for a first period of time which is an adjustable period of time.

The control transistors 32 and the capacitive elements 33 constitute a delay adjustment circuit (or a delay adjusting portion) for adjusting the delay time of the delay circuit 30. The delay circuit portion delays the input signal S_in for the adjustable period of time in response to active or in active state of the delay adjusting portion.

Each of the control transistors 32 has a pair of primary electrodes and a control terminal. The ith control transistor Tri (1≦i≦n) has a first primary electrode connected to the signal line SL and a second primary electrode connected to a first electrode of the corresponding capacitive element Ci. The capacitive element Ci has a second electrode connected to a fixed potential (a ground potential VSS in this example).

The control terminal of each of the control transistors 32 is supplied with a delay adjustment signal Sadj from the delay control circuit (40 of FIG. 4). Each of the control transistors 32 serves as a switching circuit for switching connection and disconnection between the signal line SL and the corresponding capacitive element 33 in response to the delay adjustment signal Sadj.

FIG. 4 shows a case in which an N-channel metal oxide semiconductor (MOS) transistor (NMOS) is used for the control transistors 32. In this case, when the delay adjustment signal Sadj is at a high level (H), the capacitive element 33 is connected to the signal line SL, so that the delay time of the delay circuit 30 is lengthened. Thus, the delay adjustment circuit can adjust the delay time of the delay circuit 30 in response to the delay adjustment signal from the delay control circuit.

In this example, there are n control transistors 32 and n capacitive elements 33. However, the numbers of the control transistors 32 and the capacitive elements 33 may be set arbitrarily according to a desired amount of adjustment of the delay time. Specifically, the numbers of the control transistors 32 and the capacitive elements 33 can be determined irrespective of the number of the inverter circuits 31. Furthermore, the capacity of each of the capacitive elements 33 may be set arbitrarily according to the number of the capacitive elements 33 and a desired amount of adjustment of the delay time.

Next, the delay control circuit 40 will be described with reference to FIG. 4.

The delay control circuit 40 includes a power-on reset circuit 41, a start-up counter 42, a first (frequency dividing) counter 43, a second (frequency dividing) counter 44, a reference delay signal buffer 45, a replica delay circuit 46, and a delay adjustment judgment circuit 47.

The power-on reset circuit 41 outputs a pulse signal having a predetermined pulse width as a power-on signal PON when power is supplied.

The start-up counter 42 is operable to reset an internal node in response to the power-on signal PON from the power-on reset circuit 41. Furthermore, the start-up counter 42 outputs a pre-charge signal PRE when it receives a pre-charge command signal MDPRE from the command decoder 22 after the internal node has been reset. In other words, the start-up counter 42 outputs a pre-charge signal PRE in response to a pre-charge command signal MDPRE first inputted after power has been supplied. The pre-charge command signal MDPRE is produced by the command decoder 22, which decodes a pre-charge command inputted from the DRAM controller 5.

The first counter 43 includes a divider circuit operable to perform a frequency dividing on the internal clock ICLK from the clock buffer 21 at a first dividing ratio (e.g., 2) in response to the pre-charge signal PRE and to output a first divided clock signal ICLK_div1 as a first pulse signal.

As with the first counter 43, the second counter 44 includes a divider circuit operable to perform a frequency dividing on the internal clock ICLK from the clock buffer 21 at a second dividing ratio (e.g., 3) in response to the pre-charge signal PRE and to output a second divided clock signal ICLK_div2 as a second pulse signal. The second dividing ratio of the second counter 44 is higher than the first dividing ratio of the first counter 43.

The first and the second dividing ratios of the first counter 43 and the second counter 44 are designed based on an expected delay time (designed delay time) of the delay circuit 30 of FIG. 3. Specifically, the first dividing ratio of the first counter 43 is set such that a pulse width of the first frequency-divided clock signal ICLK_div1 is equal to the expected delay time of the delay circuit 30. Hereinafter the pulse width of the first frequency-divided clock signal ICLK_div1 may be referred to as the first pulse width. The second dividing ratio of the second counter 44 is set to be ((the first dividing ratio of the first counter 43)+1).

The reference delay signal buffer 45 is operable to delay the first frequency-divided clock signal ICLK_div1 from the first counter 43 and output the delayed signal as a reference delay signal. Specifically, the reference delay signal buffer 45 serves as a reference delay signal generation circuit for generating a reference delay signal having the first pulse width along with the first counter 43. The first pulse width takes a first level during a second period of time.

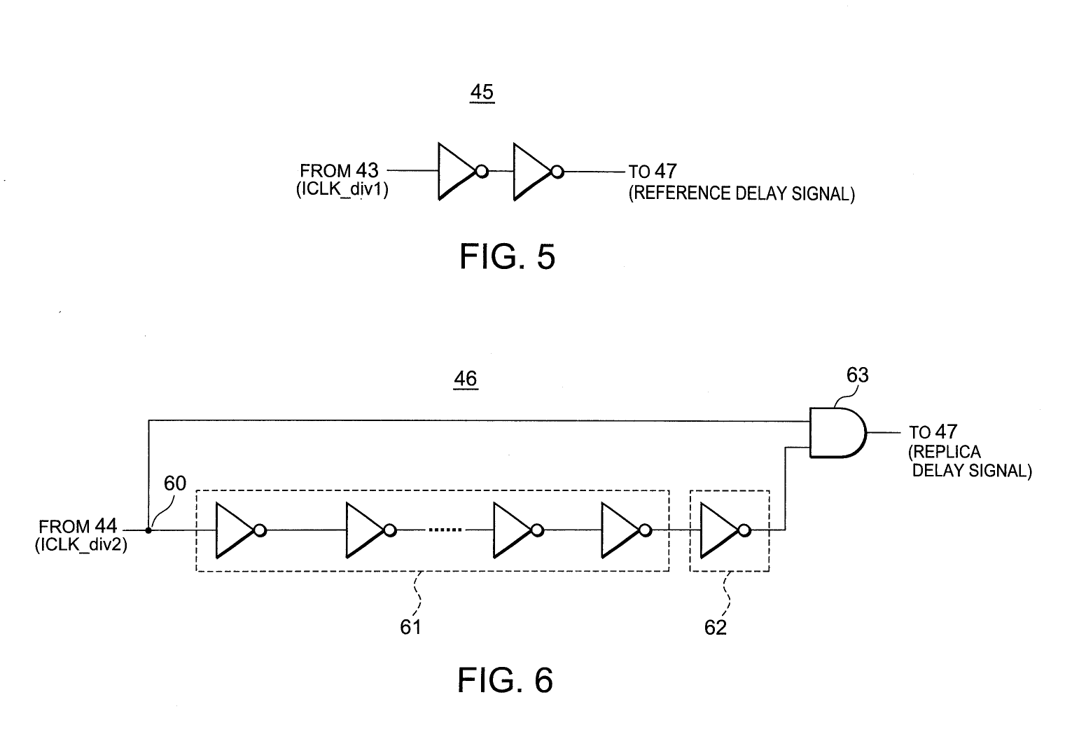

For example, the reference delay signal buffer 45 is formed by two stages of inverter circuits as shown in FIG. 5. Those inverter circuits may employ a CMOS inverter. The delay time of the reference delay signal buffer 45 is set based upon the configuration of the replica delay circuit 46.

The replica delay circuit 46 is operable to receive the second frequency-divided clock signal ICLK_div2 from the second counter 44 and to generate and output a replica delay signal. Specifically, the replica delay circuit 46 serves as a replica delay signal generation circuit for generating a replica delay signal along with the second counter 44.

More specifically, the replica delay circuit 46 is operable to output a replica delay signal having a second pulse width that is equal to the delay time of a built-in replica circuit while a rising edge of the second frequency-divided clock signal ICLK_div2 is used as a trigger. The replica circuit is a circuit simulating the delay circuit 30. The second pulse width takes a third level during a third period of time which is dependent on the first period time. Specifically, the third period of time is substantially equal in length to the first period time.

For example, as shown in FIG. 6, the replica delay circuit 46 includes a branch portion 60, a replica circuit 61, a logical inversion circuit 62, and an AND circuit 63.

The replica circuit 61 simulates the signal line SL of the delay circuit 30 (the inverter circuits 31 connected with multiple stages). In other words, the replica circuit 61 has such a configuration that the control transistors 32 and the capacitive elements 33 have been removed from the delay circuit 30. Therefore, the delay time of the replica circuit 61 is equal to the delay time of the delay circuit 30 at the time when the capacitive elements 33 are disconnected from the signal line SL (or the control transistors 32 are turned off). The delay time of the delay circuit 30 at that time is hereinafter referred to as the original delay time. The replica delay circuit 46 delays one of two branched signals of the second frequency-divided clock signal ICLK_div2 by the original delay time.

The logical inversion circuit 62 is operable to inverse the logic of the signal delayed by the replica circuit 61. The delay time of the logical inversion circuit 62 is much shorter than the delay time of the replica circuit 61 and is thus negligible.

The AND circuit 63 is operable to calculate a logical product of the other branched signal of the second frequency-divided clock signal ICLK_div2 and an output signal from the logical inversion circuit 62 and to output the logical product as a replica delay signal. The pulse width of the replica delay signal is equal to the delay time of the replica circuit 61 if the delay time of the logical inversion circuit 62 is ignored.

The delay time of the aforementioned reference delay signal buffer 45 is set to be equal to the delay time of the AND circuit 63. With this configuration, the reference delay signal from the reference delay signal buffer 45 and the replica delay signal from the replica delay circuit 46 can have rising edges at the same point in time.

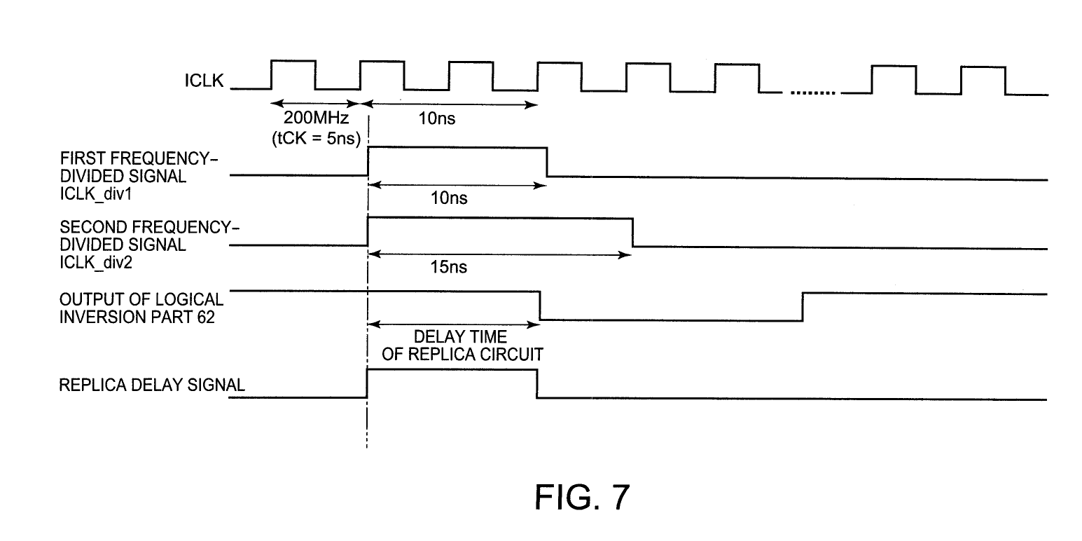

FIG. 7 is a waveform chart of various signals for understanding operation of the replica delay circuit 46. FIG. 7 shows waveforms of the internal clock signal ICLK, the first frequency-divided clock signal ICLK_div1, the second frequency-divided clock signal ICLK_div2, the output signal of the logical inversion circuit 62, and the replica delay signal. In this example, the internal clock signal ICLK has a frequency of 200 MHz (a cycle tCK of 5 ns).

As can be seen from FIG. 7, the first frequency-divided clock signal ICLK_div1 is changed from a low level (or a second level) to a high level (or the first level) at a first edge (or a rising edge) and from the high level to the low level at a second edge (or a falling edge). Similarly, the second frequency-divided clock signal ICLK_div2 is changed from a low level (or a forth level) to a high level (or the third level) at a third edge (or a rising edge) and from the high level to the low level at a forth edge (or a falling edge). The first frequency-divided clock signal ICLK_div1 and the second frequency-divided clock signal ICLK_div2 are controlled by the reference delay signal generation circuit and replica delay signal generation circuit so that the first edge is substantially equal on timing to the third edge. The replica delay signal is obtained by the replica delay circuit 46 using the first and the second frequency-divided clock signals ICLK_div1 and ICLK_div1. The pulse width of the replica delay signal is equal to the delay time of the replica circuit 61. Therefore, detection of the delay time of the replica circuit 61 is equivalent to detection of the original delay time of the delay circuit 30. In other words, a period of time corresponding to the original delay time of the delay circuit 30 can be detected by detecting the delay time of the replica circuit 61.

Referring back to FIG. 4, the delay adjustment circuit 47 serves as a judgment circuit for comparing the first pulse width of the reference delay signal with the second pulse width of the replica delay signal and outputting a delay adjustment signal Sadj based upon the comparison results. In other words, the delay adjustment circuit 47 serves as a detection circuit which detects lengths of the second period of time and the third period of time to generate the delay adjustment signal Sadj as a delay control signal in response to the lengths. The delay adjustment signal Sadj is used for rendering the delay adjusting portion one of active state and inactive state.

Specifically, the delay adjustment judgment circuit 47 compares the timing of falling edges of the replica delay signal and the reference delay signal, which have been adjusted so as to have the rising edges at the same point in time, and outputs a delay adjustment signal Sadj depending upon the comparison results. For example, if the falling edge of the replica delay signal precedes the falling edge of the reference delay signal, then the delay adjustment signal Sadj is brought into an activated state (at a high level). If the falling edge of the replica delay signal follows the falling edge of the reference delay signal, then the delay adjustment signal Sadj is brought into an inactivated state (at a low level).

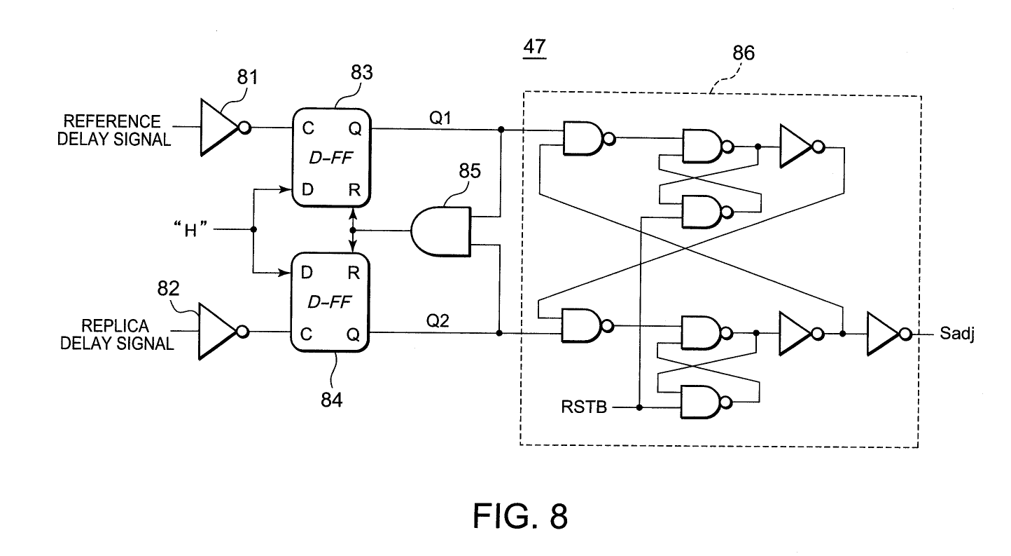

For example, as shown in FIG. 8, the delay adjustment judgment circuit 47 includes a pair of inverter circuits 81 and 82, a pair of D-flip-flops (D-FFs) 83 and 84, an AND circuit 85, and a combination logic circuit 86 including a plurality of NAND circuits and a plurality of inverter circuits.

The reference delay signal and the replica delay signal inputted to the delay adjustment judgment circuit 47 are inversed in logic by the inverter circuits 81 and 82, respectively, and supplied to clock terminals C of the D-flip-flops 83 and 84.

Each of the D-flip-flops 83 and 84 has a data terminal D fixed at a high level (H). Each of the D-flip-flops 83 and 84 outputs a high level from an output terminal Q in synchronism with a rising edge of the signal inputted to the clock terminal C. Furthermore, each of the D-flip-flops 83 and 84 outputs a low level from the output terminal Q when a signal of a high level is inputted to a reset terminal R.

The AND circuit 85 has two input terminals connected to the output terminals Q of the D-flip-flops 83 and 84 and an output terminal connected to the reset terminals R of the D-flip-flops 83 and 84. The AND circuit 85 resets the D-flip-flops 83 and 84 if an output signal Q1 of the D-flip-flop 83 and an output signal Q2 of the D-flip-flop 84 both have a high level.

The combination logic circuit 86 outputs a delay adjustment signal Sadj based upon the output signals Q1 and Q2 from the D-flip-flops 83 and 84. A reset bar signal RSTB is changed into a low level to reset the combination logic circuit 86 during starting and is then fixed at a high level.

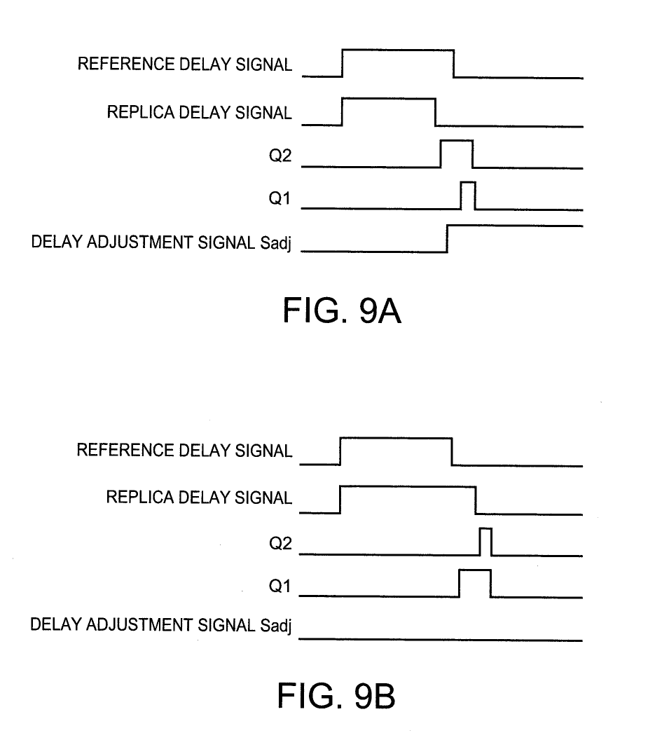

FIGS. 9A and 9B show signal waveforms at several points of the delay adjustment judgment circuit 47. FIGS. 9A and 9B are waveform charts of the reference delay signal, the replica delay signal, the output signal Q1 of the D-flip-flop 83, the output signal Q2 of the D-flip-flop 84, and the delay adjustment signal Sadj. FIG. 9A shows a case in which the delay time of the replica circuit is shorter than the expected delay time of the delay circuit 30, whereas FIG. 9B shows a case in which the delay time of the replica circuit is longer than the expected delay time of the delay circuit 30.

As shown in FIGS. 9A and 9B, the output signal Q1 changes into a high level in response to a falling edge of the reference delay signal, and the output signal Q2 changes into a high level in response to a falling edge of the replica delay signal. When both of the output signals Q1 and Q2 become a high level, the D-flip-flops 83 and 84 are reset, and the output signals Q1 and Q2 are changed into a low level.

Furthermore, as shown in FIG. 9A, when the output signal Q2 changes into a high level in a state in which the output signal Q1 is at a low level, the delay adjustment signal Sadj is accordingly changed into a high level. The delay adjustment signal Sadj maintains a high level after the output signal Q1 changes into a high level and the output signals Q1 and Q2 change into a low level.

As shown in FIG. 9B, when the output signal Q1 changes into a high level in a state in which the output signal Q2 is at a low level, the delay adjustment signal Sadj maintains a low level. The delay adjustment signal Sadj maintains a low level after the output signal Q2 changes into a high level and the output signals Q1 and Q2 change into a low level.

As can be seen from FIGS. 9A and 9B, the delay adjustment judgment circuit 47 sets the delay adjustment signal Sadj at a high level when the falling edge of the replica delay signal precedes the falling edge of the reference delay signal. In other cases, the delay adjustment judgment circuit 47 maintains the delay adjustment signal Sadj at a low level.

As described above, when the delay adjustment signal Sadj has a high level, the capacitive elements 33 are connected to the signal line SL of the delay circuit 30 (see FIG. 3), so that the delay time of the delay circuit 30 is made longer than the original delay time (the delay time of the replica circuit 61 (see FIG. 6)). When the delay adjustment signal Sadj is in an inactivated state, the delay time of the delay circuit 30 remains the same as the original delay time.

Thus, according to the present embodiment, the original delay time of the delay circuit 30 is measured during starting, and the delay time of the delay circuit 30 is adjusted (or a delay calibration process is performed) depending upon the measurement results. Therefore, during manufacturing a chip, it is not necessary to measure the delay time of the delay circuit or adjust the delay time of the delay circuit (write a control code) depending upon the measurement results. Accordingly, elimination of a test process and cost reduction caused by such elimination can be achieved.

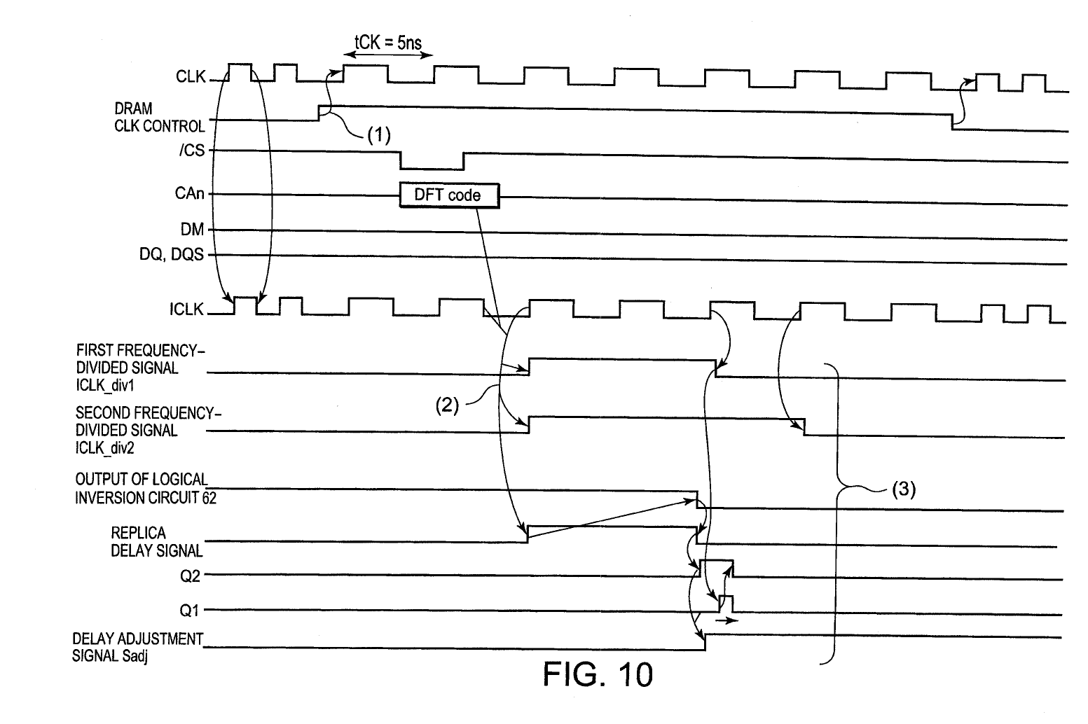

In the above description, a delay calibration process is performed during starting the semiconductor apparatus 10. Nevertheless, a delay calibration process may be performed with use of a specific command in states other than the startup. For example, a design-for-test (DFT) code, which is also simply referred to as a test code, may be used as the specific command. A delay calibration process using a DFT code will be described below with reference to FIG. 10 in addition to FIGS. 1, 7, and so forth.

FIG. 10 is a waveform chart of various signals supplied to the DRAM 20 from the DRAM controller 11 and various signals generated inside of the DRAM 20.

In a case where a delay calibration process is performed with use of a specific code, the DRAM control circuit 13 first sets the DRAM clock control signal at a high level. The DRAM clock control signal serves as a clock cycle change signal, so that the cycle of the DRAM clock CLK supplied from the clock control circuit 12 to the DRAM 20 is changed from a normal cycle into a delay calibration cycle (1). The cycle of the internal clock signal ICLK of the DRAM 20 is accordingly changed into a delay calibration cycle. The DRAM clock CLK is maintained with the delay calibration cycle while the DRAM clock control signal has a high level. For example, the delay calibration cycle tCK is 5 ns (see FIG. 7).

Next, the DRAM control circuit 13 changes the chip select signal /CS into a low level and supplies a DFT code as a command-address signal CAn to the DRAM 20. The control circuit 23 of the DRAM 20 generates a first frequency-divided signal ICL_div1 and a second frequency-divided signal ICL_div2 depending upon the DFT code and also generates a replica delay signal (2).

Then the control circuit 23 of the DRAM 20 generates a delay adjustment signal Sadj from the outputs Q1 and Q2 of the flip-flops in the delay judgment circuit (see FIG. 8) as in the case of FIG. 9A (or FIG. 9B) (3).

As described above, the semiconductor apparatus 10 according to the present embodiment can perform a delay calibration process in response to a specific command. Therefore, a delay calibration process can be performed not only during starting, but also at any desired timing.

Next, a semiconductor apparatus according to a second embodiment of the present invention will be described below. The semiconductor apparatus of the second embodiment differs from the semiconductor apparatus of the first embodiment in configuration of the delay circuit and the replica circuit.

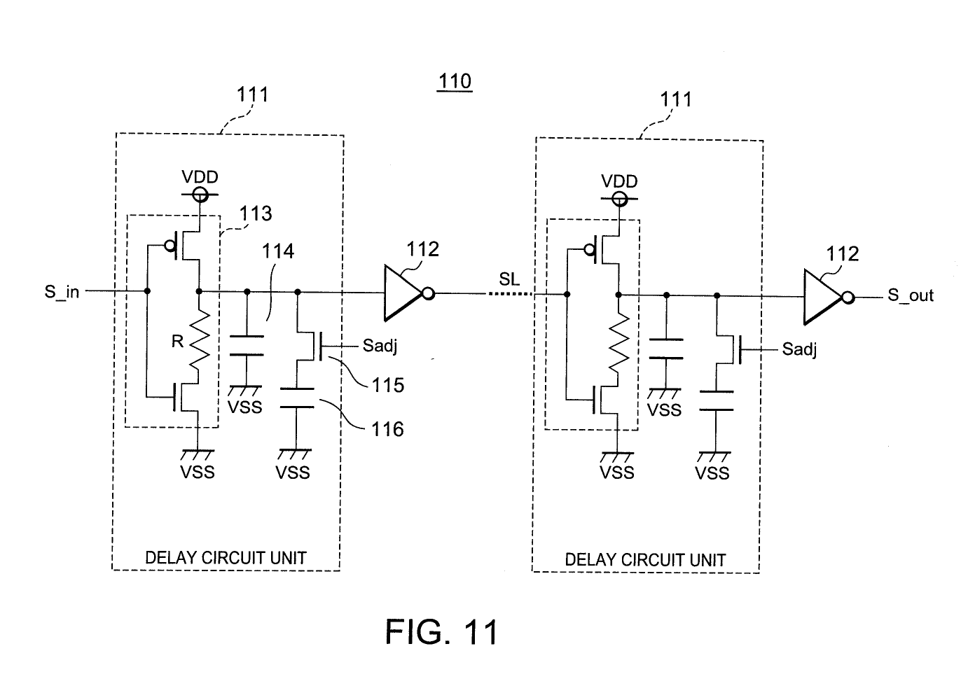

FIG. 11 shows a configuration of a delay circuit 110 used in the semiconductor apparatus of the present embodiment.

As shown in FIG. 11, the delay circuit 110 includes a plurality of delay circuit units 111 and a plurality of inverter circuits 112. The delay circuit units 111 and the inverter circuits 112 are connected in series so as to form a signal line SL.

Each of the delay circuit units 111 includes an inverter circuit 113 having a resistance element R connected between an output node and an NMOS. Each of the delay circuit units 111 further includes a first capacitive element 114 having an electrode connected to the signal line SL and an electrode connected to a ground potential VSS, which is a fixed potential. Each of the delay circuit units 111 also includes a control transistor 115 having a first primary electrode connected to the signal line SL and a control electrode to be supplied with a delay adjustment signal Sadj. Each of the delay circuit units 111 also includes a second capacitive element 116 having an electrode connected to a second primary electrode of the corresponding control transistor 115 and an electrode connected to the ground potential VSS.

The resistance element R and the first capacitive element 114 are provided in order to increase the amount of delay of the delay circuit 110 without an increase of the number of the inverter circuits 112 connected, as compared to a case in which a plurality of inverter circuits 112 are connected in series without any delay circuit units.

The second capacitive element 116 is used to adjust the amount of delay of the delay circuit 110 in response to the delay adjustment signal Sadj. The second capacitive element 116 is connected to the signal line SL when the control transistor 115 is turned on. The second capacitive element 116 is disconnected from the signal line SL when the control transistor 115 is turned off. As with the first embodiment, the control transistor 115 and the second capacitive element 116 serve as a delay adjustment circuit for adjusting the delay time of the delay circuit in response to the delay adjustment signal.

The numbers of the delay circuit units 111 and the inverter circuits 112 may arbitrarily be set based upon the expected delay time, the value of the resistance R, the capacities of the first capacitive element 114 and the second capacitive element 116, and the like. The capacities of the first capacitive element 114 and the second capacitive element 116 may arbitrarily be set based upon the delay time, the amount of adjustment of the delay time, and the like.

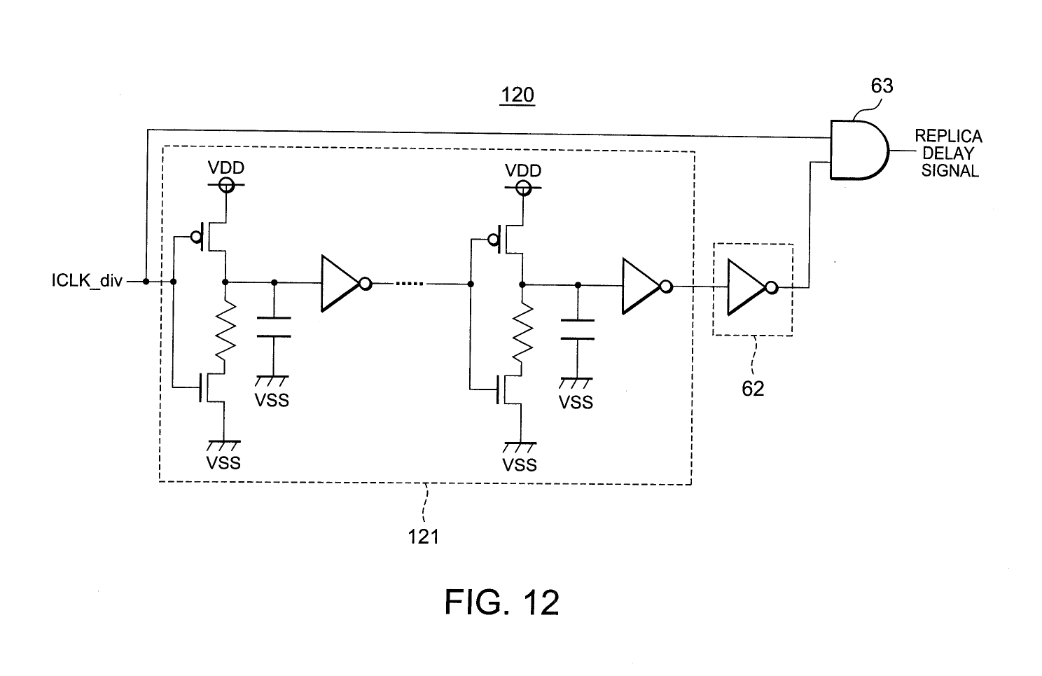

Next, a replica delay circuit used in the semiconductor apparatus according to the second embodiment will be described below with reference to FIG. 12.

A replica delay circuit 120 shown in FIG. 12 has a replica circuit 121 configured to correspond to the delay circuit 110 of FIG. 11. Specifically, the replica circuit 121 has such a configuration that the control transistors 115 and the second capacitive elements 116 have been removed from the delay circuit 110. Other portions of the replica circuit 121 are the same as in the replica delay circuit 60 of FIG. 6.

Operation of the semiconductor apparatus of the present embodiment is the same as that of the semiconductor apparatus of the first embodiment, and the explanation thereof is omitted herein.

In the semiconductor apparatus of this embodiment, the original delay time of the delay circuit 110 is measured during starting, and the delay time of the delay circuit 110 is adjusted based upon the measurement results. Therefore, during manufacturing a chip, it is not necessary to measure the delay time of the delay circuit or adjust the delay time of the delay circuit (write a control code) depending upon the measurement results. Accordingly, elimination of a test process and cost reduction caused by such elimination can be achieved. Furthermore, the delay time of the delay circuit can be adjusted at desired timing with use of a specific command.

Next, a semiconductor apparatus according to a third embodiment of the present invention will be described below. The semiconductor apparatus of the third embodiment differs from the semiconductor apparatus of the second embodiment in that the delay time of the delay circuit is adjusted not only when the delay time of the delay circuit is shorter than the expected delay time, but also when the delay time of the delay circuit is longer than the expected delay time.

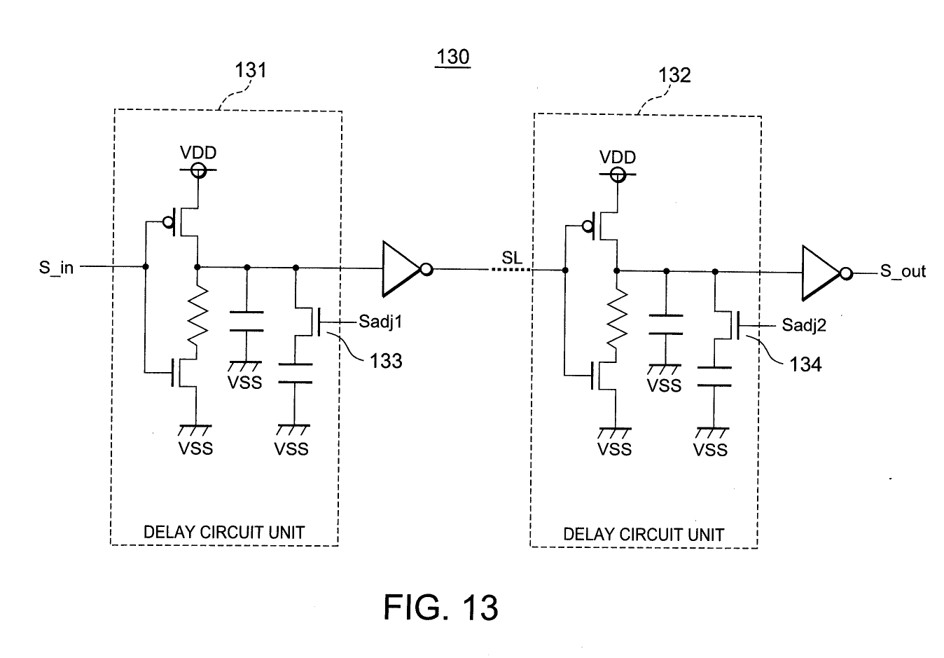

FIG. 13 shows a configuration of a delay circuit 130 included in the semiconductor apparatus of the present embodiment. The illustrated delay circuit 130 has the same configuration as the delay circuit 110 of FIG. 11. However, the delay circuit units included in the delay circuit 130 are classified into first delay circuit units 131 and second delay circuit units 132. The first delay circuit unit 131 includes a first control transistor 133 having a control terminal to be supplied with a first delay adjustment signal Sadj1. The second delay circuit unit 132 includes a second control transistor 134 having a control terminal to be supplied with a second delay adjustment signal Sadj2.

The original delay time of the delay circuit 130 is defined when one of the first and second control transistors 133 and 134 is turned on while the other is turned off. At an initial state, one of the first and second delay adjustment signals Sadj1 and Sadj2 is set at a high level, while the other is set at a low level. Thus, the delay time of the delay circuit 130 is set to be the original delay time at the initial state.

When both of the first and second control transistors 133 and 134 are turned on, the delay time of the delay circuit 130 becomes longer than the original delay time. When both of the first and second control transistors 133 and 134 are turned off, the delay time of the delay circuit 130 becomes shorter than the original delay time. The ratio of lengthening the delay time and the ratio of shortening the delay time depend upon the capacity of the capacitive elements connected to the first and second control transistors 133 and 134. The ratio of lengthening the delay time and the ratio of shortening the delay time may be set independently of each other.

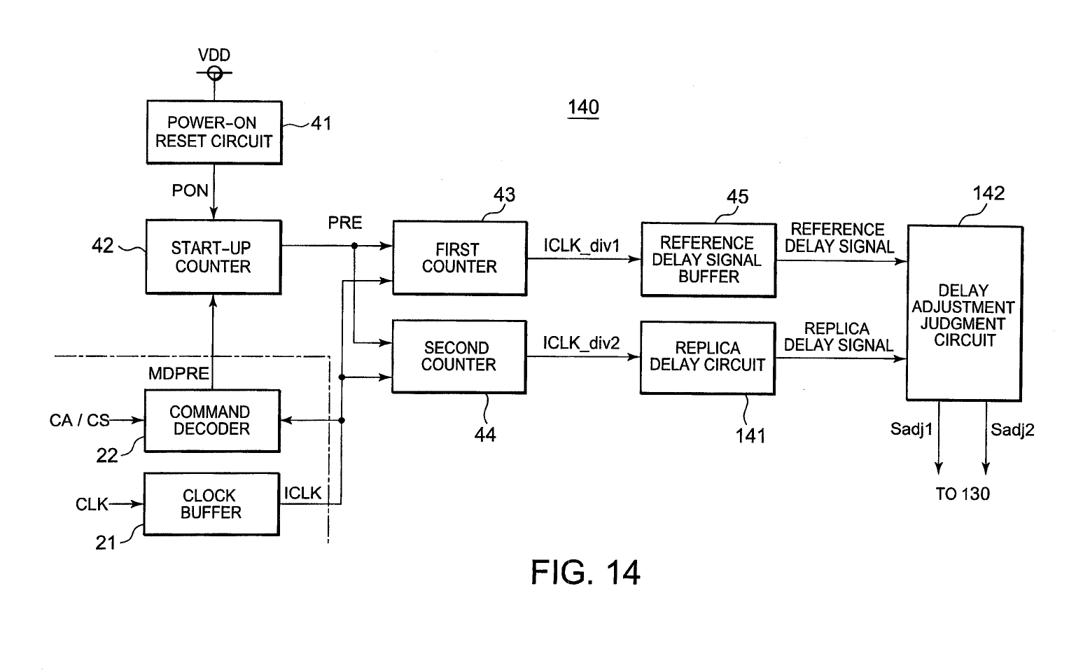

FIG. 14 shows a delay control circuit 140 included in the semiconductor apparatus of the present embodiment. The delay control circuit 140 differs from the delay control circuit 40 of FIG. 4 in that it has a replica delay circuit 141 including a replica circuit configured so as to correspond to the delay circuit 130 and in that it has a delay adjustment judgment circuit 142 for outputting first and second delay adjustment signals Sadj1 and Sadj2.

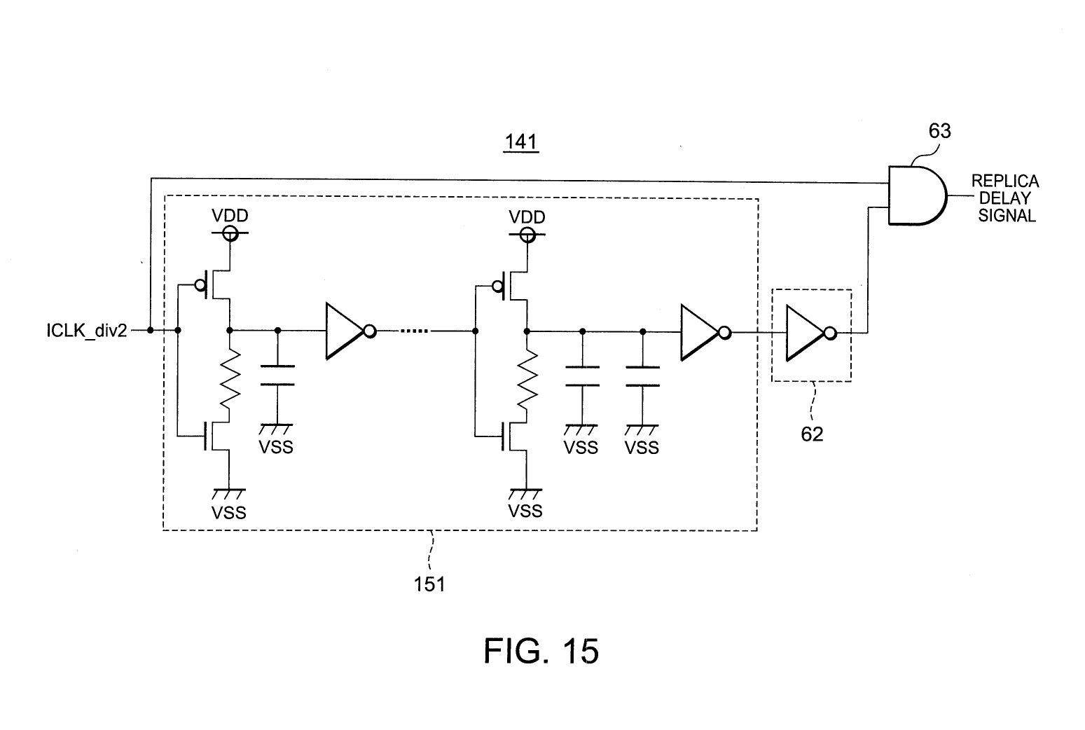

FIG. 15 shows an example of a configuration of the replica delay circuit 141. As shown in FIG. 15, a replica circuit 151 has such a configuration that the first and second control transistors 133 and 134 and the second capacitive elements corresponding to the first control transistors 133 have been removed from the delay circuit 130 of FIG. 13. The second capacitive elements corresponding to the second control transistors 134 are connected directly to the signal line SL. Therefore, the delay time of the replica circuit 151 is equal to the original delay time of the delay circuit 130.

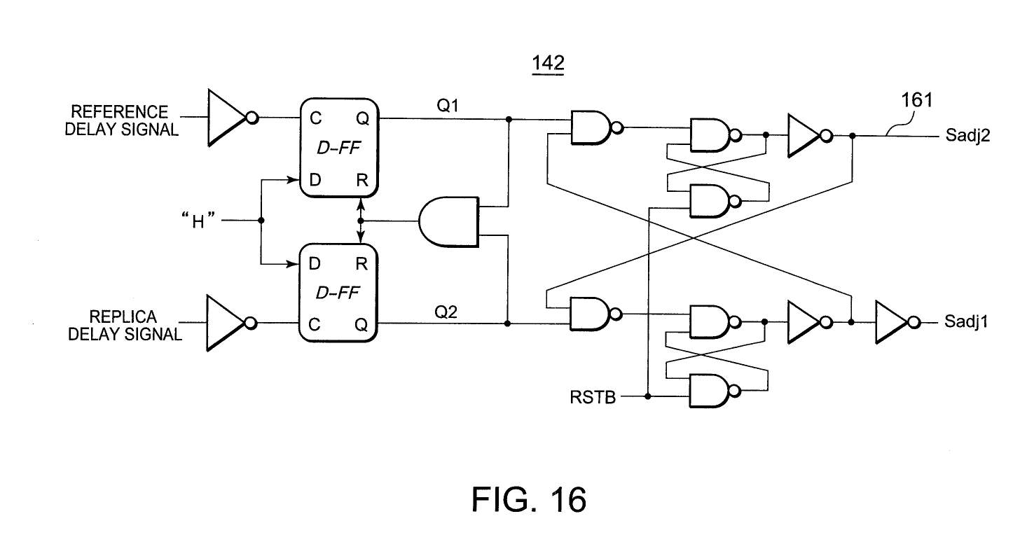

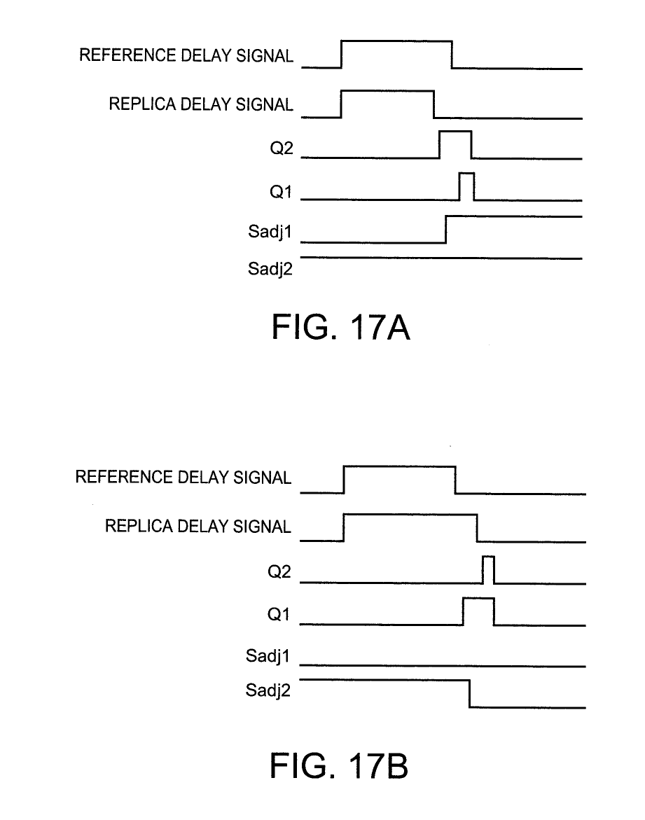

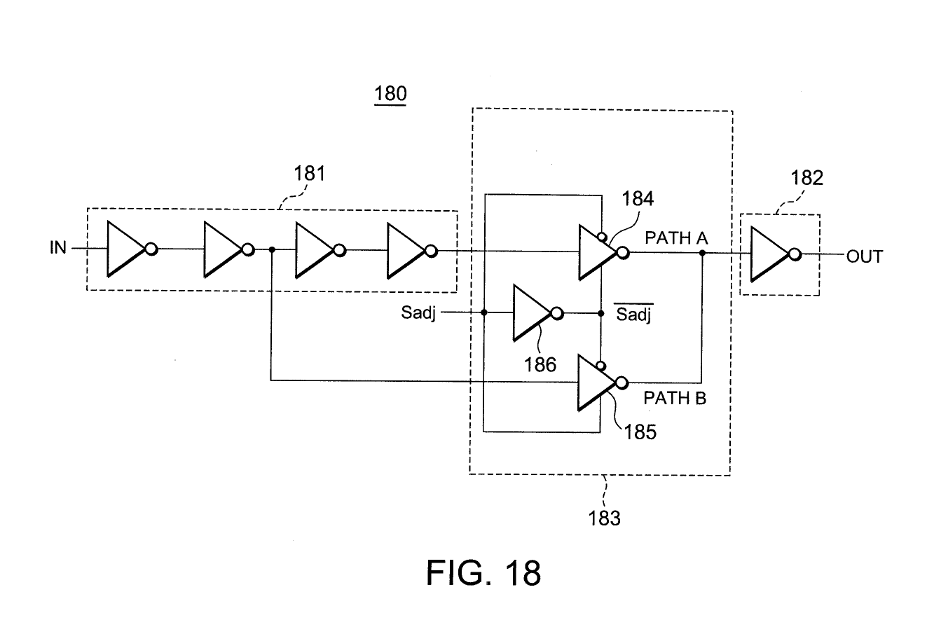

For example, as shown in FIG. 16, a delay adjustment judgment circuit 142 can be configured by adding an output part 161 for outputting a second delay adjustment signal Sadj2 to the configuration of the delay adjustment judgment circuit 80 in FIG. 8. FIGS. 17A and 17B are waveform charts of the reference delay signal, the replica delay signal, the output signals Q1 and Q2 of the D-flip-flops, and the first and second delay adjustment signals Sadj1 and Sadj2 of the delay adjustment judgment circuit 142. FIG. 17A shows a case in which the pulse width of the replica delay signal is shorter than the expected delay time of the delay circuit 130, whereas FIG. 17B shows a case in which the pulse width of the replica delay signal is longer than the expected delay time of the delay circuit 130.

As can be seen from FIG. 17A, the first delay adjustment signal Sadj1 is changed into an activated state (high level) when a falling edge of the replica delay signal precedes a falling edge of the reference delay signal. As a result, the first control transistors 133 of the delay circuit 130 shown in FIG. 13 are turned on, so that the number of the capacitive elements connected to the signal line SL increases. Accordingly, the delay time of the delay circuit 130 is made longer than the reference delay time.

Meanwhile, as can be seen from FIG. 17B, the second delay adjustment signal Sadj2 is changed into an inactivated state (low level) when a falling edge of the replica delay signal follows a falling edge of the reference delay signal. As a result, the second control transistors 134 of the delay circuit 130 shown in FIG. 13 are turned off, so that the number of the capacitive elements connected to the signal line SL decreases. Accordingly, the delay time of the delay circuit 130 is made shorter than the reference delay time.

Thus, in the semiconductor apparatus according to the present embodiment, the delay time of the delay circuit 130 can be made not only longer than the original delay time, but also shorter than the original delay time.

Next, a semiconductor apparatus according to a fourth embodiment of the present invention will be described below.

In the semiconductor apparatus of the aforementioned first embodiment, the delay time of the delay circuit 30 (signal line path SL) is adjusted by using the control transistors and the capacitive elements. In contrast, the semiconductor apparatus of this embodiment is configured to change the number of stages of the inverter circuits connected in the delay circuit (to change the path) for thereby adjusting the delay time of the delay circuit.

For example, the delay circuit of the semiconductor apparatus according to the present embodiment is configured as shown in FIG. 18.

The illustrated delay circuit 180 has a delay circuit 181 including a plurality of inverter circuits connected in series, a logical inversion circuit 182, and a selector 183 for providing two alternative selectable paths A and B between the delay circuit 181 and the logical inversion circuit 182.

The selector 183 is operable to provide a path A for supplying an output from the last stage of the inverter circuits in the delay circuit 181 to the logical inversion circuit 182 and a path B for bypassing some inverter circuits (even number) of the delay circuit 181. In this example, two inverter circuits are bypassed by the path B. The path A and the path B respectively have inverter circuits 184 and 185 with a control terminal.

The selector 183 also has an inverter circuit 186 for performing a logical inversion on the delay adjustment signal Sadj in order to bring either one of the inverter circuits 184 and 185 into an operating state in a complementary manner.

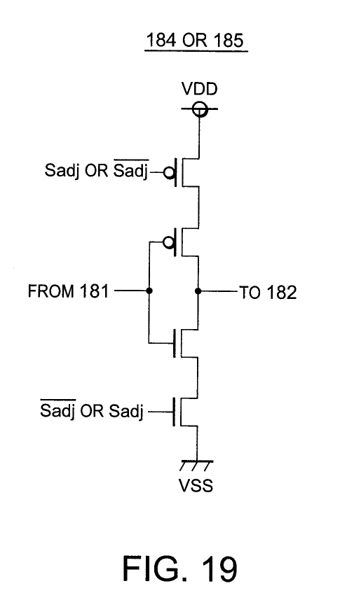

For example, each of the inverter circuits 184 and 185 is formed as shown in FIG. 19. Either one of the inverter circuits 184 and 185 is brought into an operating state by the delay adjustment signal (Sadj) and its logical inverse signal (Sadj bar).

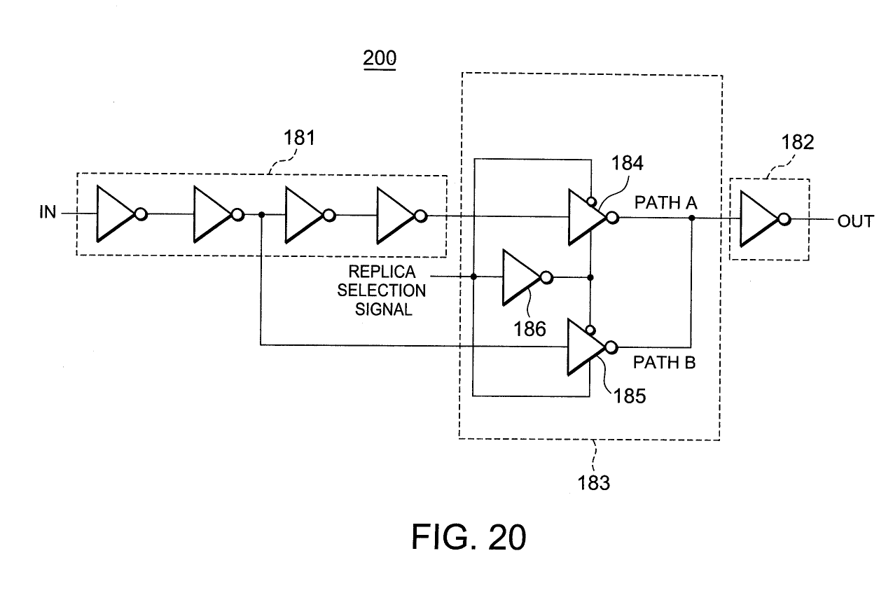

As shown in FIG. 20, a replica circuit of the semiconductor apparatus according to the present embodiment is configured in the same manner as the delay circuit 180. The delay time of the replica circuit 200 can be changed by a replica selection signal, which is supplied from the outside of the replica circuit. In the example of FIG. 20, the number of the stages of the inverter circuits in the delay circuit 181 of the replica circuit 200 can be switched between two stages and four stages. The path B is selected to allow lengthening the delay time as in the first embodiment. Conversely, the path A is selected to allow shortening the delay time.

In the semiconductor apparatus of this embodiment, the original delay time of the delay circuit 180 is detected, and the delay time of the delay circuit 180 can be adjusted based upon the detection results.

Although the present invention has been described along with some embodiments, the present invention is not limited to those embodiments. It would be apparent to those skilled in the art that various modifications may be made to the above embodiments. For example, the inverter circuits are not limited to a CMOS inverter and may have other structures. Furthermore, the control transistors are not limited to an NMOS transistor and may use other types of transistors.

What is claimed is:

1. An apparatus comprising:
a delay circuit;
a control circuit operable to detect a first period of time corresponding to a delay time of the delay circuit so as to generate a delay adjustment signal based upon the first period of time; and
a delay adjustment circuit operable to adjust the delay time of the delay circuit in response to the delay adjustment signal.

2. The apparatus according to claim 1, wherein the control circuit includes:
a reference delay signal generation circuit operable to generate a reference delay signal having a first pulse width based upon a clock signal,
a replica delay signal generation circuit operable to generate a replica delay signal having a second pulse width that is equal to the delay time of the delay circuit based upon the clock signal, and
a judgment circuit operable to compare the first pulse width with the second pulse width so as to generate the delay adjustment signal.

3. The apparatus according to claim 2, wherein the reference delay signal generation circuit includes:
a first divider circuit operable to perform a frequency dividing on the clock signal at a first dividing ratio to generate a first divided signal having the first pulse width, and
a buffer operable to delay the first divided signal and output the divided signal as the reference delay signal, and
the replica delay signal generation circuit includes:
a second divider circuit operable to perform a frequency dividing on the clock signal at a second dividing ratio higher than the first dividing ratio to generate a second divided signal,
a branch portion branching the second divided signal into two lines,
a replica circuit operable to delay a first line of the two lines of the second divided signal by a period of time that is equal to the delay time of the delay circuit,
a logical inversion circuit operable to inverse a logic of an output of the replica circuit, and
an AND circuit operable to output, as the replica delay signal, a logical product of a second line of the two lines of the second divided signal and an output of the logical inversion circuit.

4. The apparatus according to claim 2, wherein the reference delay signal and the replica delay signal are adjusted to have rising edges at the same point in time, and
the judgment circuit activates or inactivates the delay adjustment signal depending upon a temporal order of falling edges of the reference delay signal and the replica delay signal.

5. The apparatus according to claim 2, wherein the reference delay signal and the replica delay signal are adjusted to have rising edges at the same point in time, and
the judgment circuit generates, as the delay adjustment signal, a first adjustment signal and a second adjustment signal activated or inactivated depending upon a temporal order of falling edges of the reference delay signal and the replica delay signal.

6. The apparatus according to claim 1, wherein the delay adjustment circuit is included in the delay circuit.

7. The apparatus according to claim 6, wherein the delay adjustment circuit includes:
a capacitive element, and
a control transistor operable to connect the capacitive element to or disconnected the capacitive element from a signal path of the delay circuit in response to the delay adjustment signal.

8. The apparatus according to claim 6, wherein the delay adjustment circuit includes:
a bypass path bypassing part of a signal path of the delay circuit, and
a selector operable to switch between the signal path and the bypass path in response to the delay adjustment signal.

9. The apparatus according to claim 2, wherein the control circuit further includes a start-up circuit operable to start the reference delay signal generation circuit and the replica delay signal generation circuit in response to a command inputted from an outside of the control circuit.

10. The apparatus according to claim 1, further comprising:
a memory cell array including memory cells;
an address decoder operable to select the memory cells in the memory cell array; and
an address latch circuit operable to supply an address signal to the address decoder, wherein
the control circuit operable to control the address latch circuit, the control circuit including the delay circuit.

11. The apparatus according to claim 10, comprising a DRAM.

12. The apparatus according to claim 11, further comprising a controller operable to control the DRAM.

13. A device comprising:
a delay circuit including a delay circuit portion and a delay adjusting portion, the delay circuit receiving a first signal and outputting the first signal when an adjustable period of time has elapsed from receiving the first signal, the delay circuit portion delaying the first signal for a first period of time and the delay adjusting portion being rendered one of an active state and an inactive state so that the delay circuit delays the first signal for the adjustable period of time; and
a control circuit including first and second signal generation circuits, the first signal generation circuit generating a first pulse signal which takes a first level during a second period of time, the second signal generation circuit generating a second pulse signal which takes a third level during a third period of time, the third period of time being dependent on the first period of time, the control circuit further including a detection circuit detecting lengths of the second period of time and the third period of time and generating a delay control signal in response to the lengths so as to render the delay adjusting portion one of the active state and the in active state.

14. The device as claimed in claim 13, wherein the third period of time is substantially equal in length to the first period of time.

15. The device as claimed in claim 13, wherein the control circuit receives a clock signal and the first and the second signal generation circuits generate respectively the first and the second pulse signals in response to the clock signal.

16. The device as claimed in claim 13, wherein the first signal generation circuit changes the first pulse signal from a second level to the first level at a first edge and changes the first pulse signal from the first level to the second level at a second edge, the second signal generation circuit changes the second pulse signal from a fourth level to the third level at a third edge and changes the second pulse signal from the third level to the fourth level at a fourth edge, and the first and the second signal generation circuits control respectively the first and the second pulse signals so that the first edge of the first pulse signal is substantially equal in timing to the third edge of the second pulse signal.

17. The device as claimed in claim 13, wherein the delay circuit portion includes a signal line transferring the first signal and the delay adjusting portion includes a plurality of transistors and a plurality of capacitors, each of the transistors is inserted into the signal line and a corresponding one of the capacitors and receives the delay control signal at a control terminal thereof.
